(19) United States
(12) Patent Application Publication
(10) Pub. No.: US 2025/0309066 A1
(43) Pub. Date: Oct. 2, 2025

(54) PARTITIONED LEADFRAME FOR MULTI-DIE DISCRETE ELECTRONIC COMPONENTS

(71) Applicant: SEMICONDUCTOR COMPONENTS INDUSTRIES, LLC, Scottsdale, AZ (US)

(72) Inventor: Byongjin KIM, Seoul (KR)

(73) Assignee: SEMICONDUCTOR COMPONENTS INDUSTRIES, LLC, Scottsdale, AZ (US)

(21) Appl. No.: 18/621,338

(22) Filed: Mar. 29, 2024

(51) Int. Cl. H01L 23/495; H01L 21/48; H01L 21/56; H01L 23/00; H01L 23/31

(52) U.S. Cl. CPC H01L 23/49541; H01L 21/4842; H01L 21/56; H01L 23/3107; H01L 23/49575; H01L 24/48; H01L 24/32; H01L 24/73; H01L 2224/32245; H01L 2224/48137; H01L 2224/48245; H01L 2224/73265

(57) ABSTRACT

An illustrative apparatus may include a partitioned leadframe including an inner leadframe portion and an outer leadframe portion. The inner leadframe portion may be at least partially surrounded by the outer leadframe portion and may be electrically isolated from the outer leadframe portion. The apparatus may further include a first die attached to the partitioned leadframe, a second die attached to the partitioned leadframe, and a molding material encapsulating the first die, the second die, and at least a portion of the partitioned leadframe. The molding material may be recessed between the inner leadframe portion and the outer leadframe portion so as to leave a cavity on a side of the partitioned leadframe opposite the first die. Corresponding apparatuses, and methods for constructing them are also disclosed.

### TECHNICAL FIELD

This description relates to ways of packaging electronic apparatuses such as discrete electronic components.

### BACKGROUND

Packaging plays a critical role in ensuring the proper function, reliability, and case of use of discrete electronic components. Proper packaging of discrete electronic components may serve various roles. For example, one function of a package may be to protect a delicate silicon die inside the package from physical damage, contamination, electrostatic discharge (ESD), etc., since these threats could render the component inoperable if the component is not properly shielded. Similarly, the package may also provide a barrier against moisture and exposure to other environmental elements that could lead to corrosion and malfunction of the component. Another role of the package may be to facilitate electrical connections between the internal circuitry of the component and the external circuit board. For example, metal pins, leads, bumps, and other such features may allow for the electrical component to be soldered onto or otherwise connected to a circuit board. Heat dissipation may also be provided by packaging that is configured to facilitate heat transfer away from operational elements of the component (e.g., the die inside the package). Packaging may also include markings or labels that indicate important information about the component (e.g., a part number, manufacturer, electrical specifications, etc.) to facilitate proper identification, handling, and placement on the circuit board.

### SUMMARY

While various benefits may be gained by embedding multiple semiconductor dies in a single discrete package, a challenge arises with respect to ensuring that the dies are electrically isolated within the package (or, more precisely, that desired electrical connections between the dies are limited to electrically-conducting interconnects such as wires or other configurable connections, rather than the dies being attached to a same conductive plane such as a leadframe). To address this challenge, implementations described herein relate to partitioned leadframes for multi-die discrete electronic components. Specifically, these implementations involve partitioning a leadframe into multiple, electrically-isolated portions, such as an inner portion and an outer portion that at least partially surrounds the inner portion. In this way, different dies can be attached to the different portions and the dies will be electrically isolated such that the only current flow between them will be via electrically-conducting die interconnects specifically disposed for that purpose (e.g., wires, leads, clips, ribbons, interposers, chiplet semiconductor bridges, etc.). Apparatuses constructed with these characteristics (e.g., multi-die discrete electronic components) are described herein, as well as methods (e.g., manufacturing processes, etc.) for constructing such apparatuses.

In one example implementation, an apparatus described herein includes: a partitioned leadframe, a first die, a second die, and a molding material. The partitioned leadframe includes an inner leadframe portion and an outer leadframe portion, the inner leadframe portion being at least partially surrounded by the outer leadframe portion and being electrically isolated from the outer leadframe portion. The first die is attached to the partitioned leadframe (e.g., to one of the inner leadframe portion or the outer leadframe portion) and the second die is also attached to the partitioned leadframe (e.g., to the other of the inner leadframe portion or the outer leadframe portion). The molding material encapsulates the first die, the second die, and at least a portion of the partitioned leadframe. Additionally, as a result of the method of manufacturing (as described in more detail below), the molding material in this implementation may be recessed between the inner leadframe portion and the outer leadframe portion so as to leave a cavity on a side of the partitioned leadframe opposite the first die.

An apparatus such as the implementation described above may be implemented with a variety of additional elements, features, characteristics, and so forth.

For example, in certain implementations of the apparatus, the dies of the apparatus may be fabricated using substrates of different substrate materials. For instance, the first die may be fabricated using a silicon substrate and the second die may be fabricated using a silicon carbide substrate.

In certain implementations of the apparatus, the first die and the second die could both be fabricated using a substrate of a same substrate material (e.g., a silicon substrate, a silicon carbide substrate, etc.).

In certain implementations of the apparatus, the first die may be attached to the inner leadframe portion, the second die may be attached to the outer leadframe portion, the apparatus may further comprise a die interconnect (e.g., a wire, a lead, a clip, a ribbon, an interposer, a chiplet semiconductor bridge, etc.) electrically connecting a top side of the first die to a top side of the second die, and the molding material may further encapsulate the die interconnect.

In certain implementations of the apparatus, the first die may be attached to the inner leadframe portion, the second die may be attached to the outer leadframe portion, the apparatus may further comprise a die interconnect electrically connecting the inner leadframe portion to a top side of the second die, a bottom side of the first die may be electrically connected to the inner leadframe portion, and the molding material may further encapsulate the die interconnect.

In certain implementations of the apparatus, the partitioned leadframe may further include a plurality of leads arranged adjacent to the outer leadframe portion. The apparatus may then further comprise a first die interconnect electrically connecting the first die to a first lead of the plurality of leads and a second die interconnect electrically connecting the second die to a second lead of the plurality of leads.

In certain implementations of the apparatus, the cavity may have a trapezoidal cross section between the inner leadframe portion and the outer leadframe portion.

In certain implementations of the apparatus, the apparatus may implement a discrete cascode circuit, the first die may be attached to the inner leadframe portion and may implement a first transistor of the discrete cascode circuit, and the second die may be attached to the outer leadframe portion and may implement a second transistor of the discrete cascode circuit.

Another implementation of an apparatus described herein also includes a partitioned leadframe, a first die, a second die, and a molding material. In this example, the partitioned leadframe again includes an inner leadframe portion and an outer leadframe portion, the inner leadframe portion being at least partially surrounded by the outer leadframe portion and being and electrically isolated from the outer leadframe portion. Moreover, the first die is again attached to the partitioned leadframe preform (e.g., to one of the inner leadframe portion or the outer leadframe portion) and the second die is also attached to the partitioned leadframe preform (e.g., to the other of the inner leadframe portion or the outer leadframe portion). A first molding material for this apparatus fills at least a portion of a space between the inner leadframe portion and the outer leadframe portion. A second molding material for this apparatus then encapsulates the first die, the second die, and at least a portion of the partitioned leadframe.

As with the first apparatus described above, this apparatus too may be implemented with a variety of additional elements, features, characteristics, and so forth. The same variations described above may be implemented for this apparatus. For example, the first die may be fabricated using a silicon substrate and the second die may be fabricated using a silicon carbide substrate. As another example, the first die may be attached to the inner leadframe portion, the second die may be attached to the outer leadframe portion, the apparatus may further comprise a die interconnect electrically connecting the first die to the second die, and the second molding material may further encapsulate the die interconnect. Additionally, certain variations of this apparatus may be different from those described above. For instance, in certain implementations, the first molding material may be different from the second molding material, while in other implementations, the first molding material may be the same as the second molding material.

An example method for producing an apparatus (such as the first apparatus described above) includes: 1) forming a partitioned leadframe preform that includes an inner leadframe portion and an outer leadframe portion, the inner leadframe portion being at least partially surrounded by the outer leadframe portion and being physically connected to the outer leadframe portion via a tie bar (e.g., a connecting component); 2) removing a first portion of the tie bar; 3) attaching a first die to the partitioned leadframe preform; 4) attaching a second die to the partitioned leadframe preform; 5) encapsulating the first die, the second die, and at least a portion of the partitioned leadframe preform in a molding material; and 6) removing, after the encapsulating, a second portion of the tic bar such that the inner leadframe portion becomes electrically isolated from the outer leadframe portion.

When this method is performed in certain examples, the first die may be fabricated using a silicon substrate and the second die may be fabricated using a silicon carbide substrate. When this method is performed is certain examples, the removing of the second portion of the tic bar may be performed by cutting away the second portion of the tic bar using a mechanical tool or a laser. When this method is performed is certain examples, the tic bar may be one of a plurality of tie bars physically connecting the inner leadframe portion to the outer leadframe portion; the inner leadframe portion may be shaped as a polygon having a plurality of sides that are each physically connected to the outer leadframe portion via at least one of the plurality of tic bars; and the method may further include: 1) removing, before the encapsulating, respective first portions of each of the plurality of tic bars other than the tic bar, and 2) removing, after the encapsulating, respective second portions of each of the plurality of tic bars other than the tic bar.

Another example method for producing an apparatus (such as the second apparatus described above) includes: 1) forming a partitioned leadframe preform that includes an inner leadframe portion and an outer leadframe portion, the inner leadframe portion being at least partially surrounded by the outer leadframe portion and being physically connected to the outer leadframe portion via a tie bar; 2) removing a first portion of the tie bar; 3) filling at least a portion of a space between the inner leadframe portion and the outer leadframe portion with a first molding material; 4) removing, after the filling at least the portion of the space between the inner leadframe portion and the outer leadframe portion, a second portion of the tie bar such that the inner leadframe portion becomes electrically isolated from the outer leadframe portion; and 5) after the inner leadframe portion becomes electrically isolated from the outer leadframe portion: (a) attaching a first die to the partitioned leadframe preform; (b) attaching a second die to the partitioned leadframe preform; and (c) encapsulating the first die, the second die, and at least a portion of the partitioned leadframe preform in a second molding material.

When this method is performed in certain examples, the first die may be fabricated using a silicon substrate and the second die may be fabricated using a silicon carbide substrate. When this method is performed in certain examples, the removing the second portion of the tie bar may be performed by etching or grinding the second portion of the tie bar to thereby remove the tie bar. When this method is performed in certain examples, the tie bar may be one of a plurality of tie bars physically connecting the inner leadframe portion to the outer leadframe portion; the inner leadframe portion may be shaped as a polygon having a plurality of sides that are each physically connected to the outer leadframe portion via at least one of the plurality of tic bars; and the method may further include: 1) removing, before the filling at least the portion of the space between the inner leadframe portion and the outer leadframe portion, respective first portions of each of the plurality of tie bars other than the tie bar, and 2) removing, after the filling at least the portion of the space between the inner leadframe portion and the outer leadframe portion, respective second portions of each of the plurality of tie bars other than the tie bar.

The details of these and other implementations are set forth in the accompanying drawings and the description below. Other features will also be apparent from the following description, drawings, and claims.

### BRIEF DESCRIPTION OF THE DRAWINGS

FIGS. 1A-1C show different views of an example leadframe to illustrate certain challenges that may be presented if this leadframe were to host a multi-die discrete electronic component.

FIGS. 2A-2C show different views of example partitioned leadframes that overcome the challenges illustrated in FIGS. 1A-1C when used for a multi-die discrete electronic component in accordance with principles described herein.

FIG. 3 shows an illustrative method for producing a multi-die discrete electronic component with a partitioned leadframe in accordance with principles described herein.

FIG. 4 shows a top view of a partitioned leadframe preform that may be used in performing the method of FIG. 3 in accordance with principles described herein.

FIGS. 5A-5F show side views of an apparatus at various stages of construction using the method of FIG. 3 in accordance with principles described herein.

FIG. 6 shows another illustrative method for producing a multi-die discrete electronic component with a partitioned leadframe in accordance with principles described herein.

FIG. 7 shows a top view of a partitioned leadframe preform that may be used in performing the method of FIG. 6 in accordance with principles described herein.

FIGS. 8A-8G show side views of an apparatus at various stages of construction using the method of FIG. 6 in accordance with principles described herein.

### DETAILED DESCRIPTION

Discrete electronic components such as discrete transistors generally include a single semiconductor die within a package configured to expose connections to the die and otherwise protect and facilitate proper function and use of the component. Even for integrated circuit components that potentially include large numbers of electronic devices (e.g., complex chips with many transistors, resistors, capacitors, etc.), a single die on which the integrated circuit is constructed is generally packaged by itself to form an individual chip.

There are certain applications, however, where it may be convenient for a plurality of dies to be included together in a single package. For example, while certain transistor dies (e.g., semiconductor dies for power transistors configured to handle large voltages, large amounts of current, etc.) could be individually packaged as discrete components, it may also be convenient for certain combinations of such transistor dies to be packaged together into a single discrete component. For instance, rather than the conventional approach of forming a cascode circuit with two or more transistors by connecting multiple discrete transistor components on a circuit board, it could be advantageous to integrate two or more separate transistor dies in a single package in which they are properly connected to form the cascode circuit. In this way, a discrete cascode chip is produced that may behave equivalently as would multiple discrete components connected individually to a circuit board, but with added technical benefits such as saving space, saving power, adding convenience (e.g., only needing to handle one component instead of multiple components, eliminating a need to connect the components to form the cascode circuit, etc.), and so forth.

At least one technical problem or challenge that may arise with the prospect of including multiple dies in a single package relates to isolation of the dies from one another. For a single-die component, the die would generally be attached to (e.g., soldered to, sintered to, or otherwise coupled with) a leadframe and wire bonding or another suitable technique would be used to connect the die appropriately to various leads included within the leadframe prior to later package steps such as encasing the die, interconnects, and leadframe in a molding material. When multiple dies are to be packaged in a single discrete component, however, the process is not so straightforward. While certain connections between the dies within the component may ultimately be needed (e.g., so as to form the cascode circuit or whatever other type of circuit is being targeted), it would not generally be desirable for the multiple dies to be attached to a same conductive plane (e.g., such as a leadframe). Rather, it may be desirable for the dies to be electrically isolated from one another in their placement in the package, and for appropriate connections to be made using wire bonding or the like after placement.

Hence, a technical problem that arises is that a single package would generally have a single portion of the leadframe that is configured to host the die, but disposing multiple dies on this portion of the leadframe would fail to electrically isolate the dies and would short them together in an undesirable way. Given the problems with attaching the dies directly to the same leadframe, techniques using a direct bonded copper (DBC) substrate or direct plated copper (DPC) substrate could be employed to isolate one die from the other on the same leadframe. For example, at least one of the dies could be attached to the leadframe by way of a non-conductive ceramic substrate sandwiched between layers of copper so as to electrically isolate the dies from the leadframe itself (and thereby from one another). For example, a soldering operation (in which a die is attached to a DBC substrate using a soldering material) or a sintering operation (in which the die is attached to the DBC substrate using a sintering material such as silver) may be used. However, this approach may be accompanied by a new set of problems. For example, the layers of copper and ceramic lifting the die (or dies) off the leadframe may contribute significantly to the ultimate thickness of the discrete component, reducing flexibility for applications in which a thin, low-profile component is desirable. Moreover, other issues with DBC and DPC techniques may include relatively high manufacturing cost, potentially lower reliability (e.g., lower thermal conductivity, weaker bond strength, etc.), and so forth.

Accordingly, implementations described herein present technical solutions to the technical problem of isolating multiple dies in a single discrete package without introducing significant additional costs or other issues associated with DBC and/or DPC approaches to the problem. Specifically, as will be described in detail below, implementations described herein provide partitioned leadframes for multi-die discrete electronic components. Rather than having a single portion of the leadframe that hosts all the dies of the component, methods described herein are configured to produce distinct, electrically-isolated portions of the leadframe to host the different dies. For example, an inner portion of the leadframe may be at least partially surrounded (and, in some cases, entirely surrounded) by an outer portion of the leadframe, and each of these portions may be electrically isolated from one another so as to be adapted for hosting separate dies (e.g., including dies associated with the same or different semiconductor substrates) that will likewise be isolated from one another without requiring costly processes such as DBC or DPC processes.

A variety of technical effects and benefits may be provided by partitioned leadframe implementations described herein for multi-die discrete electronic components. For example, as mentioned above, certain space savings, power savings, and added convenience may be enjoyed by consolidating multiple discrete transistors into a single discrete component configured to perform a common role (e.g., the role of a cascode circuit, etc.). Moreover, due to the isolated portions of the leadframe produced in the manner described herein, this multi-die package need not require a DBC process (and the cost and profile/clearance issues associated therewith), but rather may have a small and low-profile form factor. Manufacturing of the multi-die electrical components may also be relatively low cost and simplified compared with processes involving advanced techniques such as DBC or DPC processes.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Partitioned leadframes for multi-die discrete electronic components may produce any or all of the technical benefits mentioned above, as well as various additional technical benefits that will be described and/or made apparent below.

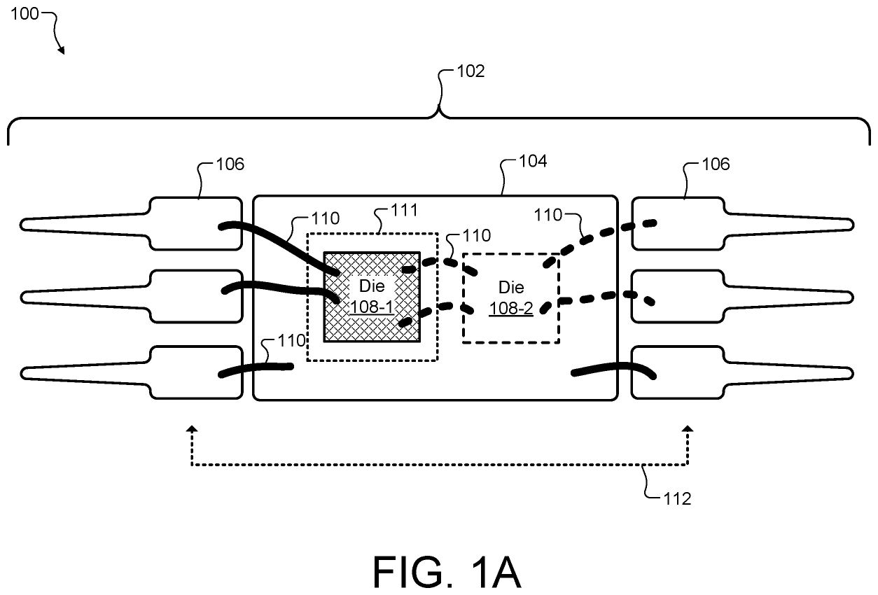

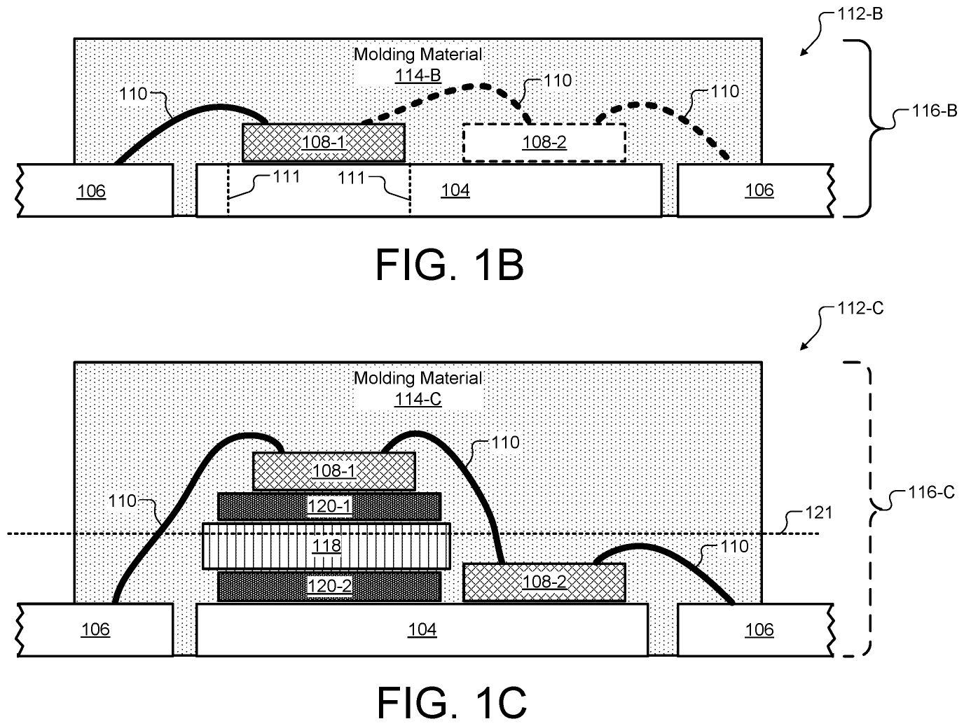

FIGS. 1A-1C show different views of an example leadframe to illustrate certain challenges that may be presented if this leadframe were used to host a multi-die discrete electronic component. For example, the challenges may arise if the leadframe is used in manufacturing a discrete electronic component that includes multiple dies, such as a discrete cascode circuit with two power transistors each implemented on a different die.

FIG. 1A shows a top view 100 of a leadframe 102 that is shown to include a main portion 104 along with a plurality of leads 106 (only some of which are explicitly labeled). However, while main portion 104 clearly includes sufficient space (e.g., as well as die pads, etc., not explicitly shown) to host both a first die 108-1 and a second die 108-2, a problem would arise were both of these dies 108-1 and 108-2 to be attached to main portion 104 in the manner suggested by FIG. 1A. Specifically, even given that there is ample room on main portion 104 to host both dies 108-1 and 108-2, certain undesirable connections and/or other issues may result from die 108-2 being attached to the same main portion 104 of leadframe 102 once die 108-1 has been placed. Since leadframe 102 is formed from a conductive material (e.g., copper or another suitable metal), attaching both dies 108-1 and 108-2 to main portion 104 would short the dies together in an undesirable way that may not comport with the intended interconnections for the multi-die discrete electronic component that is to ultimately be produced.

For example, as shown, a plurality of electrically-conductive die interconnects 110 (also referred to as interconnects 110) is shown to provide various electrical connections. For example, certain interconnects 110 provide electrical connections between the two dies 108-1 and 108-2, other interconnects 110 provide electrical connections between one of the dies and a particular lead 106, and still other interconnects 110 (referred to only as interconnects, rather than die interconnects in this case) provide electrical connections between different portions of the leadframe (e.g., from main portion 104 to a lead 106, as shown in FIG. 1A). Interconnects 110 may be implemented by any suitable electrically-conductive material as may serve to connect to the elements shown and to transfer electrical current between them. For example, in the examples explicitly illustrated herein, interconnects 110 are illustrated as wires that make electrical connections between the dies and the various parts of the leadframe. In other examples, it will be understood that other electrically-conductive die interconnects (besides wires) may additionally or alternatively be employed, including leads, clips, ribbons, interposers, chiplet semiconductor bridges, and so forth.

To illustrate the challenge in FIG. 1A, die 108-2 is drawn using dashed lines suggesting that it may be problematic to place this element in the configuration shown (i.e., without addressing the challenge in some way). Similarly, while FIG. 1A shows that it may ultimately be desirable for the dies to be connected to various leads 106 and/or to be interconnected to one another by interconnects 110 (e.g., by way of wire bonding techniques or the like), certain interconnects 110 connecting to die 108-2 are drawn using dashed lines to suggest that the challenge needs to be addressed before die 108-2 can properly be placed and connected. As with leads 106, it is noted that only some interconnects 110 are explicitly labeled in FIG. 1A, though it will be understood that all the interconnects shown in the figure may be referred to as interconnects 110.

It will be understood that if one of dies 108-1 or 108-2 is isolated from the other, a multi-die (including hybrid die) discrete electronic component may be made functional and properly packaged. For example, if the part of main portion 104 within a box 111 surrounding die 108-1 were to be isolated from the rest of the leadframe, the issues described with die 108-2 would be resolved.

FIGS. 1B and 1C show side views of leadframe 102 to illustrate certain aspects that will now be described. An indicator at the bottom of FIG. 1A illustrates the perspective of side views 112, then FIGS. 1B and 1C illustrate respective examples of side views 112 of different implementations of apparatuses (e.g., discrete electrical components) that could be constructed (including the problems that the implementations would present). Specifically, a side view 112-B of one example apparatus is shown in FIG. 1B and a side view 112-C of another example apparatus is shown in FIG. 1C.

In side view 112-B in FIG. 1B, main portion 104 is shown to host both dies 108-1 and 108-2 (e.g., attached to the leadframe by way of a solder, sinter, conductive adhesive, or other suitable material not explicitly shown in this figure), while a few example interconnects 110 are shown to connect dies 108-1 and 108-2 to each other and to example leads 106. For the same reasons described above, dies 108-2 and interconnects 110 connected thereto are depicted with dashed lines suggesting that the illustrated placement and connections introduce a problem that needs to be addressed for proper construction of the circuit. As described above in relation to FIG. 1A, if die 108-1 could be isolated from the rest of main portion 104. the multi-die discrete electronic component would not have the problems described. Accordingly, the side view of box 111 is shown to cut through main portion 104 on either side of die 108-1 to show how die 108-1 would be fully isolated from die 108-2 in this scenario.

As further shown in side view 112-B, a molding material 114-B may be added to encapsulate dies 108-1 and 108-2, at least a portion of leadframe 102 (e.g., main portion 104 and parts of the leads 106), and the various interconnects 110 (e.g., after the interconnects have been bonded to make the desirable connections). This molding material 114-B may hold everything together to ensure that the dies remain protected from electrostatic discharge and external contaminants such as dirt and moisture, as well as to ensure that the interconnects 110 remain securely connected and the geometric configuration of the main portion 104 and the leads 106 remains stable.

Molding material 114-B is shown in FIG. 1B to have a thickness 116-B, which may represent a relatively small and low-profile thickness desirable for the electronic component that is ultimately produced. For example, the low profile represented by thickness 116-B may allow for flexibility in how the discrete electronic component is used in operation (e.g., where it can fit, etc.). However, as has been mentioned, even if the example illustrated in side view 112-B has a suitable thickness 116-B, the isolation problem with die 108-2 is not addressed in this example.

Conversely, in side view 112-C in FIG. 1C, main portion 104 is again shown to host both dies 108-1 and 108-2 (with example interconnects 110 making the same connections between the dies and to leads 106), but now the isolation problem is addressed by die 108-1 being lifted off main portion 104 using a direct bonded copper (DBC) substrate. Specifically, as shown, a non-conductive ceramic plate 118 held between bonded copper layers 120-1 and 120-2 (to define a DBC) may hold die 108-1 away from main portion 104 such that die 108-1 is electrically isolated from main portion 104 (and thus also from die 108-2). The bonded copper layers 120-1 and 120-2 (which can include any type of metal layer) can define one or more traces and/or one or more heatsinks (or portions thereof).

To indicate that the isolation issue is addressed, it is noted that FIG. 1C no longer uses the dashed lines for die 108-2 and the interconnects 110 attached thereto. However, a thickness 116-C of a molding material 114-C that encapsulates the various elements (i.e., dies 108-1 and 108-2, bonded copper layers 120-1 and 120-2 with the ceramic plate 118 between them, interconnects 110, main portion 104 and parts of leads 106) is now drawn with dashed lines indicating that the thickness of the package itself may now pose a problem. Specifically, in contrast to the low profile shown by thickness 116-B above, the DBC-based solution to the isolation problem presented by the component in FIG. 1C is shown to require a molding material 114-C with a significantly thicker profile indicated by thickness 116-C. If not for the DBC, a line 121 shows approximately where a top of molding material 114-C could be, thereby making the electrical component significantly thinner. In other words, line 121 illustrates that implementations described herein that dispense with the DBC may be far lower profile than illustrated by thickness 116-C. Other undesirable consequences of the DBC-based approach process (e.g., cost, less reliability, etc.) may also be understood to potentially accompany this approach, though those problems are not explicitly illustrated.

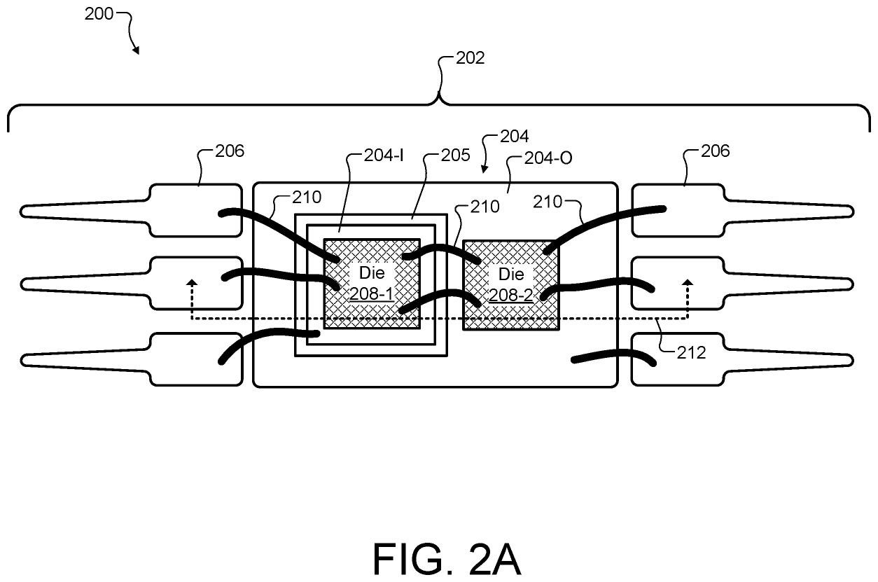

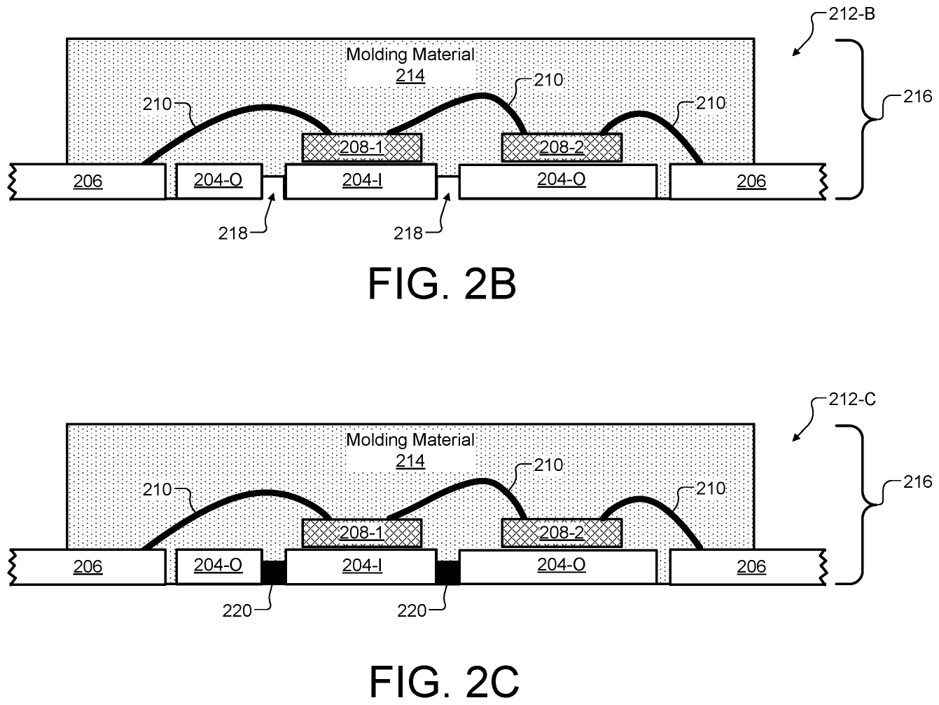

To address the deficiencies and challenges illustrated in FIGS. 1A-1C, implementations described herein present partitioned leadframes for multi-die discrete electronic components. For example, FIGS. 2A-2C show different views of example partitioned leadframes that may overcome the challenges and deficiencies illustrated in FIGS. 1A-1C when used for a multi-die discrete electronic component in accordance with principles described herein.

FIG. 2A shows a top view 200 of a partitioned leadframe 202 that is shown to include a main portion 204 corresponding to main portion 104 of leadframe 102. However, whereas main portion 104 was a single conductive plate, main portion 204 is shown to be partitioned into an inner leadframe portion 204-I (‘I’ for “Inner”) and an outer leadframe portion 204-O (‘O’ for “Outer”) that are electrically disconnected or isolated from one another by a space 205. Leadframes including this type of partitioning of the main portion 204 into two or more leadframe portions (such as inner leadframe portion 204-I and outer leadframe portion 204-O) are referred to herein as partitioned leadframes. Accordingly, while leadframe 102 of FIGS. 1A-1C may represent a conventional (non-partitioned) leadframe, the leadframe shown in FIGS. 2A-2C, with its partitioned main portion 204, is referred to as partitioned leadframe 202. Other aspects of partitioned leadframe 202 and the apparatus (e.g., discrete electronic component) being constructed in this example are shown to be similar to those described above in relation to FIGS. 1A-1C. For example, the main portion 204 is shown to be flanked by various leads 206 that are also part of partitioned leadframe 202. Two dies 208-1 and 208-2 are shown to be attached to partitioned leadframe 202 (e.g., to main portion 204) and to be connected to leads 206 and to one another by way of one or more electrically-conductive die interconnects 210 (also referred to as interconnects 210), which may be implemented in various ways as described above in relation to interconnects 110. More particularly, the first die 208-1 is shown to be attached to inner leadframe portion 204-1 and the second die 208-2 is shown to be attached to outer leadframe portion 204-O such that the dies are electrically isolated by space 205 and only connected to one another by interconnects 210. As will be described in more detail below, the dies 208-1 and 208-2 may be attached to the respective leadframe portions 204-1 and 204-O in any suitable way, such as using a soldering technique, a sintering technique, a fusion bonding technique, or the like.

Apparatuses such as shown in FIGS. 2A-2C may implement any circuits or discrete electrical components as may serve a particular implementation. As one example that has been mentioned, the apparatus may implement a discrete cascode circuit, where first die 208-1 is attached to inner leadframe portion 204-I and implements a first transistor of the discrete cascode circuit and where second die 208-2 is attached to outer leadframe portion 204-O and implements a second transistor of the discrete cascode circuit. In other examples, the same principles illustrated here may be used to form other suitable multi-die electrical components (e.g., other than cascode circuits), including any circuit as may otherwise use two or more discrete components (e.g., discrete transistor components, discrete resistor components, etc.) and that provides a benefit when packaged as a single discrete electronic circuit.

FIGS. 2B and 2C show side views of leadframe 202 to illustrate certain aspects such as how a partitioned leadframe such as partitioned leadframe 202 may address the isolation and profile issues described above in relation to FIGS. 1A-1C. Using similar notation as described above, an indicator at the bottom of FIG. 2A illustrates the perspective of side views 212, then FIGS. 2B and 2C illustrate respective examples of side views 212 of different implementations of apparatuses (e.g., discrete electrical components) that could be constructed to address the problems described above. Specifically, a side view 212-B of one example apparatus is shown in FIG. 2B, and a side view 212-C of another example apparatus is shown in FIG. 2C.

As will be described and set forth below, apparatuses such as illustrated in FIGS. 2A-2C may be implemented in a variety of ways and with a variety of optional features that may be used in any combination as may serve a particular implementation. The illustrations in FIGS. 2A-2C are therefore presented as high-level representation of certain features that may be common to many or all of the multi-die discrete electronic components using partitioned leadframes described herein, and various additional implementations with different specific features and combinations of features as will be described in relation to these figures.

As shown in FIG. 2B, the apparatus illustrated in side view 212-B may include the partitioned leadframe 202 (shown from the side and not explicitly labeled in this figure) with its inner leadframe portion 204-I and outer leadframe portion 204-O. As illustrated from both top view 200 and side view 212-B, inner leadframe portion 204-I may be at least partially surrounded by outer leadframe portion 204-O so as to be electrically isolated from outer leadframe portion 204-O. In this case, top view 200 shows inner leadframe portion 204-I to be an island that is completely surrounded by outer leadframe portion 204-O (with space 205 in between). Similarly, side view 212-B shows inner leadframe portion 204-I to be surrounded on both sides by outer leadframe portion 204-O. Due to this isolation of inner and outer portions of the main portion 204 of partitioned leadframe 202, the only connections between dies attached to these different portions will be those connections explicitly provided for by electrically-conductive interconnects (as described in more detail below) and there will not be an electrical connection via the leadframe itself (as was the problem described and illustrated above in relation to FIGS. 1A and 1B).

As further shown in side view 212-B, the apparatus may include both the first die 208-1 and the second die 208-2 attached to partitioned leadframe 202. Though no material is explicitly shown to attach the dies to the leadframe in this figure, it will be understood (and illustrated in more detail below) that a material such as solder or a sintering material may be used. As shown, die 208-1 is attached to a top side of inner leadframe portion 204-I while die 208-2 is attached to a top side of outer leadframe portion 204-O. While this and other examples illustrated herein include this configuration of the dies and the leadframe portions, it will be understood that other configurations may be used in certain implementations. For example, one or both of the dies 208-1 and 208-2 may be attached to a bottom side of one of the leadframe portions (rather than to the top). As another example, the second die 208-2 could be attached to the inner leadframe portion 204-I while the first die 208-1 could be attached to the outer leadframe portion 204-O. If isolation between the dies is not needed or desired, both dies (or additional dies not shown in FIG. 2B) could be attached to the same leadframe portion (e.g., two dies both attached to outer leadframe portion 204-O). If isolation between the dies is desirable, however, one die will be attached to one of the leadframe portions 204-1 or 204-O while the other die will be attached to the other leadframe portion (i.e., so that space 205 and the electrical isolation provided thereby will be positioned between the dies).

The two dies 208-1 and 208-2 may be implemented by any suitable dies as may serve a particular implementation. In some implementations, the dies may be similar or identical dies that may perform similar or identical functions and may even have been manufactured on a same wafer or the like. For instance, the first die 208-1 and the second die 208-2 may both be fabricated using a substrate of a same substrate material. For instance, both dies 208-1 and 208-2 could be fabricated using a silicon (Si) substrate, a silicon carbide (SiC) substrate, a gallium nitride (GaN) substrate, a gallium arsenide (GaAs) substrate, an indium phosphide (InP) substrate, or another suitable semiconductor substrate. In other implementations, the dies may have various differences. For instance, the two dies 208-1 and 208-2 may be of different sizes, may have different functions, and may have been manufactured on different wafers, on different substrates, and/or using different processes or technologies. Implementations employing a combination of dies fabricated using different substrate materials may be referred to as hybrid die implementations. For instance, in one hybrid die implementation example, the first die 208-1 may be fabricated using a silicon (Si) substrate while the second die 208-2 may be fabricated using a silicon carbide (SiC) substrate. Equivalently, the first die 208-1 may be fabricated using the silicon carbide (SIC) substrate while the second die 208-2 may be fabricated using the silicon (Si) substrate.

The apparatus shown in FIG. 2B is further shown to include interconnects 210 connecting various components such as dies 208-1 and 208-2 and leads 206. While not explicitly shown in FIG. 2B, it will also be understood that interconnects 210 may, in certain implementations, connect other elements of the apparatus (e.g., connecting a die to a leadframe portion, connecting a leadframe portion to a lead, etc.). A few specific examples of connections will now be described.

In a first example connection explicitly illustrated in FIG. 2B, first die 208-1 is shown to be attached to inner leadframe portion 204-I, second die 208-2 is shown to be attached to outer leadframe portion 204-O, and an interconnect 210 is shown to electrically connect a top side of first die 208-1 to a top side of second die 208-2. Alternatively, in a second example connection not explicitly illustrated in FIG. 2B, the first die 208-1 may again be attached to inner leadframe portion 204-I and the second die 208-2 may again be attached to outer leadframe portion 204-O. However, rather than connecting the top sides of the two dies, an interconnect in this example may electrically connect inner leadframe portion 204-1 to a top side of second die 208-2. Assuming that a bottom side of first die 208-1 is electrically connected to inner leadframe portion 204-I, this connection serves as a way of electrically connecting the bottom side of first die 208-1 to the top side of second die 208-2. Similarly, in another example connection not explicitly illustrated in FIG. 2B, the dies 208-1 and 208-2 may again be attached, respectively, to inner leadframe portion 204-I and outer leadframe portion 204-O. In this example, however, an interconnect in this example may electrically connect outer leadframe portion 204-O to a top side of first die 208-1. Assuming that a bottom side of second die 208-2 is electrically connected to outer leadframe portion 204-O, this connection would similarly serve as a way of electrically connecting the bottom side of second die 208-2 to the top side of first die 208-1.

Another example connection explicitly illustrated in FIG. 2B involves the plurality of leads 206 included in partitioned leadframe 202 and arranged adjacent to outer leadframe portion 204-O. For this connection, a first interconnect 210 electrically connects first die 208-1 to a first lead 206 of the plurality of leads and a second interconnect 210 electrically connects second die 208-2 to a second lead 206 (e.g., a different lead) of the plurality of leads, as shown. Similarly as described above, other connections may be made to the bottom sides of dies 208-1 and/or 208-2 by those bottom sides being electrically connected to the respective leadframe portions and the leadframe portions being electrically connected to the leads 206. All of these interconnections may be implemented using wire bonding techniques or other suitable ways of interconnecting dies and/or portions of a leadframe.

As further shown in FIG. 2B, the apparatus may include a molding material 214 encapsulating first die 208-1, second die 208-2, and at least a portion of partitioned leadframe 202 (e.g., at least part of inner leadframe portion 204-I, at least part of outer leadframe portion 204-O, and at least part of the leads 206). As shown, the molding material may be recessed between inner leadframe portion 204-I and outer leadframe portion 204-O so as to leave at least one cavity 218 on a side of partitioned leadframe 202 opposite first die 208-1 (i.e., on the bottom side of partitioned leadframe 202 that, in this case, happens to be opposite both dies 208-1 and 208-2). As shown, molding material 214 may not only encapsulate dies 208-1 and 208-2 and the portions of partitioned leadframe 202, but may further encapsulate each of the various interconnects 210 so as to hold the interconnects in place and prevent them from being strained, inadvertently disconnected, or the like. As described above in relation to molding material 114-B and 114-C, molding material 214 may further perform structural and protective roles for the apparatus by, for example, keeping dust and moisture away from dies 208-1 and 208-2 and by holding the various portions of partitioned leadframe 202 (e.g., inner leadframe portion 204-I, outer leadframe portion 204-O, and leads 206) structurally in place.

Side view 212-B depicts two cavities 218 on either side of inner leadframe portion 204-I (i.e., in the space 205 between inner leadframe portion 204-I and outer leadframe portion 204-O). While cavities 218 may not serve a particular function, they may be found on a finished apparatus (e.g., a finished discrete electrical component) as an artefact of how the apparatus was constructed or manufactured. Specifically, as will be described in more detail below, cavities 218 may be present as a result of one or more tie bars that held inner leadframe portion 204-1 in place in the middle of outer leadframe portion 204-O until molding material 214 was added to perform its structural role. At that point, removal of the tie bars (to thereby break the electrical connection between inner leadframe portion 204-1 and outer leadframe portion 204-O) leaves cavities 218 as an artefact of the tic bars.

As illustrated by a width 216 in FIG. 2B, the problems associated with the lack of isolation (illustrated in FIGS. 1A and 1B) and the overly thick profile (illustrated by thickness 116-C in FIG. 1C) of the apparatuses illustrated above may both be simultaneously addressed by the apparatus illustrated in FIG. 2B. As shown, the dies 208-1 and 208-2 are each placed directly on the partitioned leadframe 202 so as to provide a low-profile width 216, while at the same time being isolated from one another due to the partitioning of inner leadframe portion 204-I from outer leadframe portion 204-O.

FIG. 2C shows another similar apparatus that provides these same benefits and addresses the problems in the same ways. However, as will be described in more detail below, the apparatus of FIG. 2C may be manufactured in a different manner and, as such, may ultimately have slightly different artefacts to reveal that mode of manufacturing. More specifically, as shown, the apparatus of FIG. 2C includes the partitioned leadframe 202 including the inner leadframe portion 204-I and the outer leadframe portion 204-O, as well as the leads 206. As illustrated in FIGS. 2A and 2C, inner leadframe portion 204-I is again at least partially surrounded by outer leadframe portion 204-O and is electrically isolated from outer leadframe portion 204-O. In this apparatus, first die 208-1 is again attached to partitioned leadframe 202 at inner leadframe portion 204-1, while second die 208-2 is again attached to partitioned leadframe 202 at outer leadframe portion 204-O. However, rather than the cavities 218 illustrated as artefacts of the manufacturing process in FIG. 2B (under the recessed molding material 214), the apparatus of FIG. 2C shows both: 1) a first molding material 220 filling at least a portion of space 205 between inner leadframe portion 204-I and outer leadframe portion 204-O, and 2) a second molding material (i.e., molding material 214) encapsulating first die 208-1, second die 208-2, interconnects 210, and at least a portion of the partitioned leadframe 202.

The first molding material 220 may be the same or different from molding material 214, but, as will be described in more detail below, it will be understood that these may be distinguishable at least as a result of being applied at different times during the manufacturing process. Specifically, while cavities 218 were described as being artefacts of tic bars removed (e.g., cut) at the end of the process when molding material 214 was already in place, molding material 220 may be put in place near the beginning of the process as partitioned leadframe 202 is being prepared. For example, tie bars on the top side of the leadframe may hold inner leadframe portion 204-1 in place in the middle of the surrounding outer leadframe portion 204-O and first molding material 220 may be added to what will become the bottom side of partitioned leadframe 202. Thereafter, the tic bars may be removed to leave a partitioned leadframe 202 that is held together by first molding material 220. Thereafter, other steps of the process may be performed such as attaching the dies 208-1 and 208-2, bonding the interconnects 210, and, finally, encapsulating the elements of the apparatus in molding material 214.

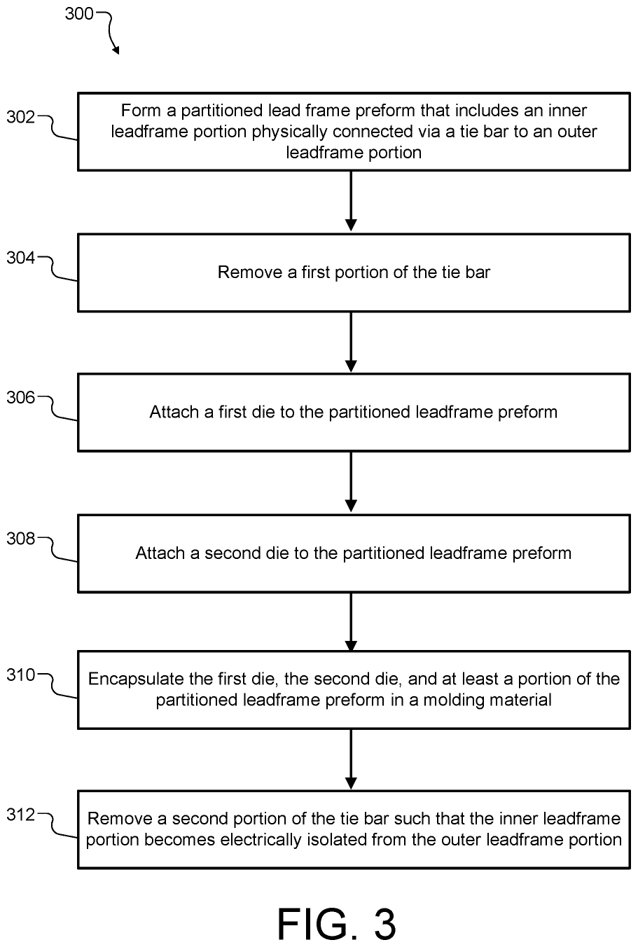

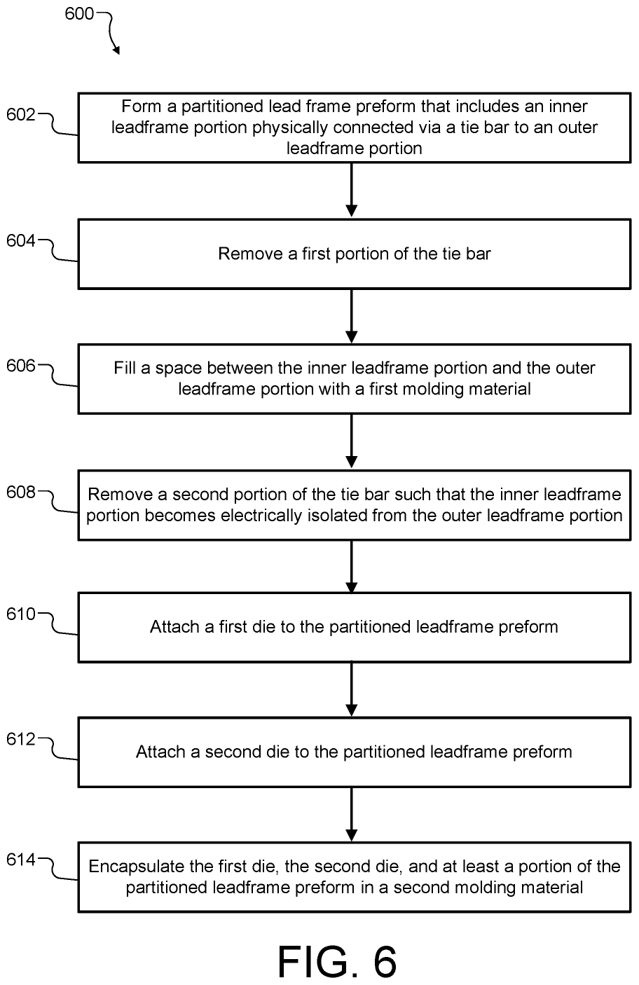

Details for how each of the apparatuses of FIGS. 2B and 2C may be constructed will now be described in relation to FIGS. 3-8G. Specifically, FIG. 3 shows an illustrative method for producing a multi-die discrete electronic component with a partitioned leadframe such as the apparatus illustrated in FIG. 2B and FIGS. 4 and 5A-5F show various aspects and stages of that process. FIG. 6 then shows another illustrative method for producing a multi-die discrete electronic component with a partitioned leadframe such as the apparatus illustrated in FIG. 2C and FIGS. 7 and 8A-8G show various aspects and stages of that process.

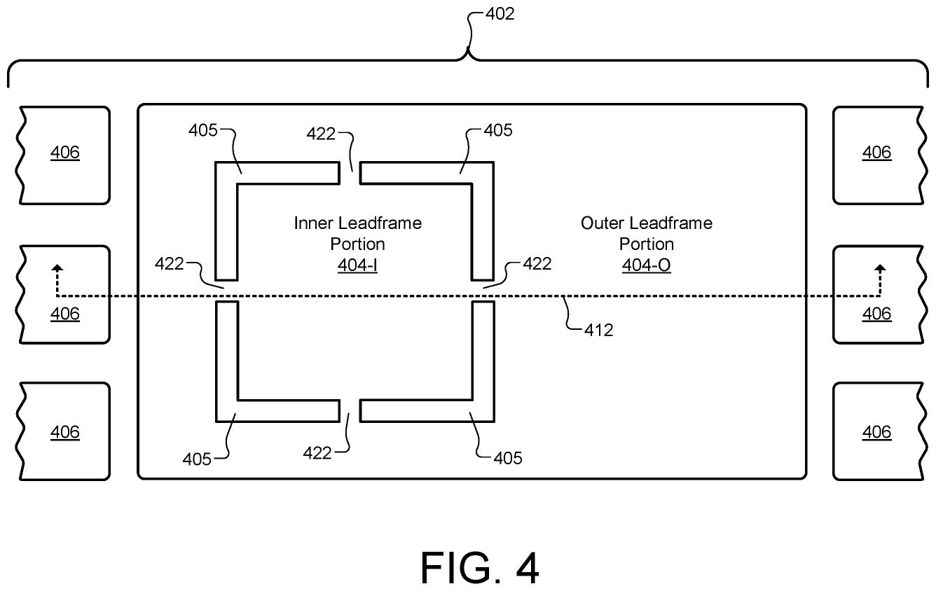

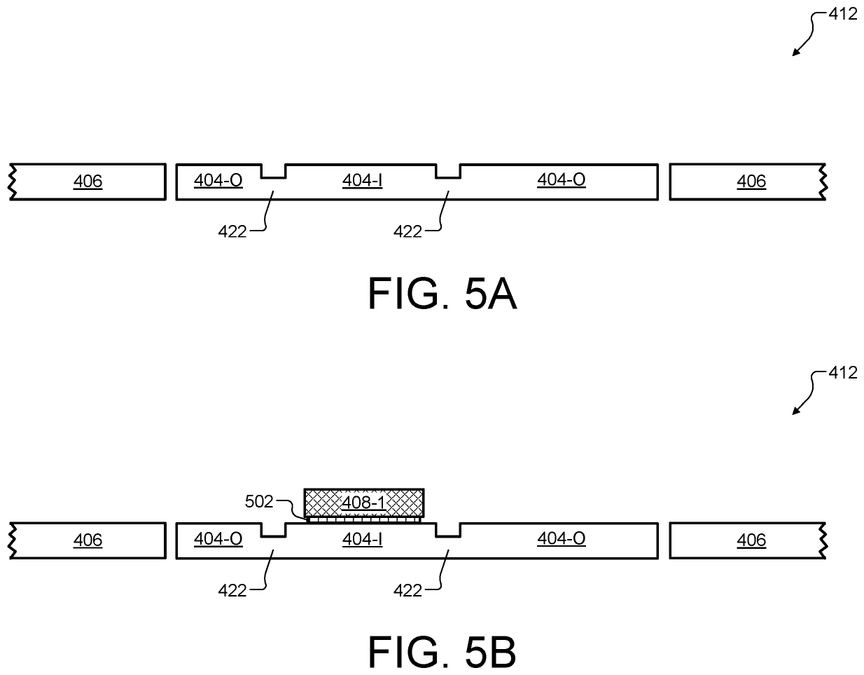

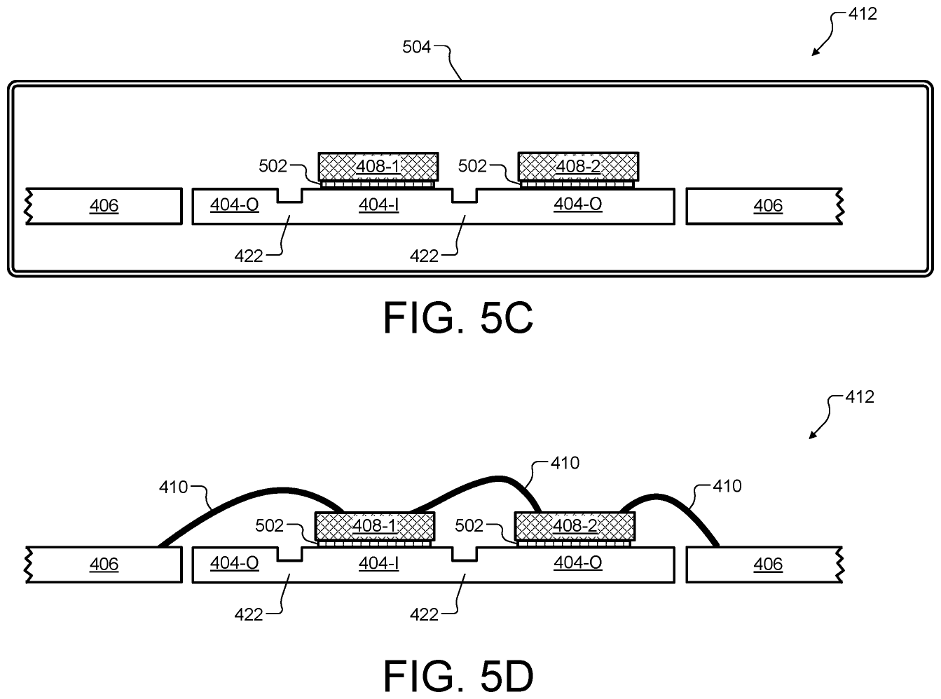

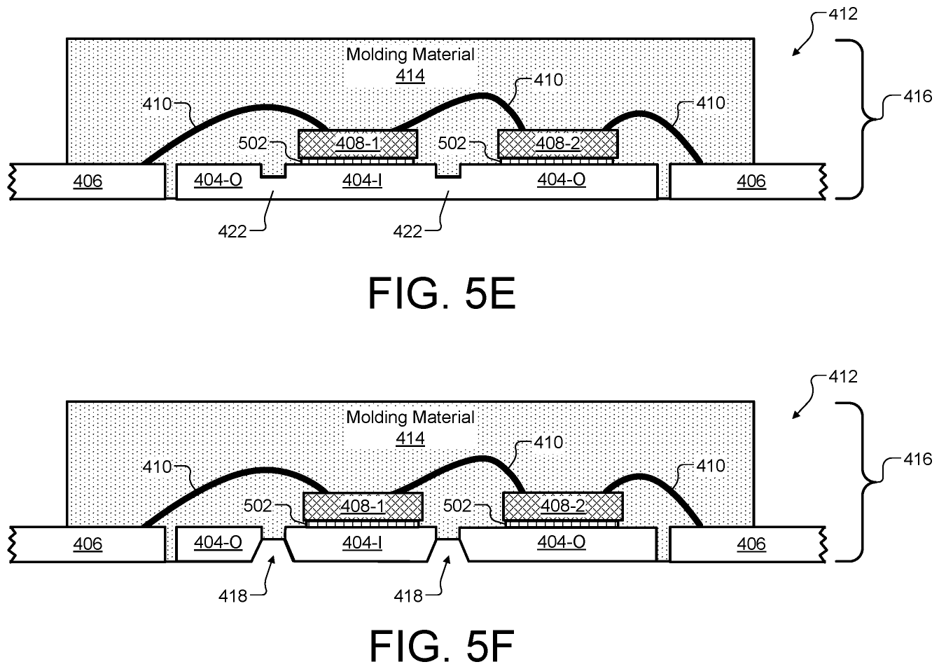

In FIG. 3, an illustrative method 300 for constructing a multi-die discrete electronic component with a partitioned leadframe is shown to include a plurality of operations 302-312 in accordance with principles described herein. More particularly, method 300 represents a method for constructing an apparatus such as the multi-die discrete electronic component described above in relation to FIG. 2B. While FIG. 3 shows illustrative operations 302-312 according to one implementation, other implementations of method 300 may omit, add to, reorder, and/or modify any of the operations 302-312 shown in FIG. 3 (although, as will be noted, the order of certain operations may be more relevant than others). In some examples, multiple operations shown in FIG. 3 or described in relation to FIG. 3 may be performed concurrently (e.g., in parallel) with one another, rather than being performed sequentially as illustrated and/or described. Each of operations 302-312 will now be described in more detail in relation to not only FIG. 3 but also FIGS. 4 and 5A-5F.

Operation 302 of method 300 involves forming a partitioned leadframe preform that includes an inner leadframe portion and an outer leadframe portion. The partitioned leadframe preform may be formed at operation 302 by stamping (e.g., stamping a copper sheet with a pattern of the partitioned leadframe preform), cutting, etching, or using any other suitable technique. As used herein, a leadframe preform refers to the leadframe in an unfinished state (e.g., before structural elements such as tie bars have been removed to form the final leadframe). As such, the partitioned leadframe preform formed at operation 302 may be similar to partitioned leadframes described above (e.g., partitioned leadframe 202) except that, at this stage of the process, the preform may still include certain characteristics not to be found in the final partitioned leadframe. For example, while the inner leadframe portion of the partitioned leadframe preform formed at operation 302 may be at least partially surrounded by the outer leadframe portion, the inner leadframe portion may not yet be electrically isolated from the outer leadframe portion since the inner leadframe portion may need to be structurally held in place during the manufacturing process. To this end, for instance, the inner leadframe portion may be physically connected to the outer leadframe portion via one or more tic bars.

To illustrate, FIG. 4 shows a top view of a partitioned leadframe preform 402 that may be used in performing method 300 in accordance with principles described herein. For example, partitioned leadframe preform 402 may represent the partitioned leadframe preform 402 that is formed at operation 302 (e.g., by stamping, cutting, etching, etc.). As shown, partitioned leadframe preform 402 includes various elements numbered with a similar number scheme as the elements of the partitioned leadframe 202 described above. More specifically, partitioned leadframe preform 402 includes an inner leadframe portion 404-I, an outer leadframe portion 404-O that fully surrounds inner leadframe portion 404-I, a space 405 (in four L-shaped portions for the preform) between inner leadframe portion 404-I and outer leadframe portion 404-O, and a plurality of leads 406 (shown in part in FIG. 4, though it will be understood that these leads may be full leads similar to those shown in other examples above). A plurality of tie bars 422 is shown to break up space 405 between inner leadframe portion 404-I and outer leadframe portion 404-O. As described above, these tie bars 422 may hold inner leadframe portion 404-I in place during much of the manufacturing process, but may ultimately be fully removed or at least broken so as to leave inner leadframe portion 404-I electrically isolated from outer leadframe portion 404-O in the final product. While partitioned leadframe preform 402 is shown in top view in FIG. 4, each of FIGS. 5A-5F will show partitioned leadframe preform 402 in a side view 412 whose perspective is shown by an indicator in FIG. 4.

While only one tie bar 422 may technically be needed to hold inner leadframe portion 404-I in place during the manufacturing process, FIG. 4 shows that, in at least some implementations, that tie bar may be one of a plurality of tic bars 422 physically connecting inner leadframe portion 404-I to outer leadframe portion 404-O. For example, multiple tie bars may provide additional stability for inner leadframe portion 404-I to ensure that it remains in its proper position throughout the process. As shown, inner leadframe portion 404-I may be shaped as a polygon having a plurality of sides that are each physically connected to outer leadframe portion 404-O via at least one of the plurality of tie bars 422. For example, in this case, inner leadframe portion 404-I is shaped as a square having four sides that each physically connect to outer leadframe portion 404-O via exactly one tie bar 422. In other implementations, however, inner leadframe portion 404-I could take another suitable polygonal shape (e.g., a triangle, a rectangle, etc.) and each side may have any suitable number of tie bars (e.g., zero tie bars, one tie bar, two tie bars, etc.). One or two tie bars 422 will be explicitly described and/or illustrated as being removed in multiple portions in examples illustrated and described below. However, it will be understood that the manufacturing process may involve removing (before the encapsulating) respective first portions of each of the plurality of tie bars 422, and removing (after the encapsulating) respective second portions of each of the plurality of tie bars 422.

Returning to FIG. 3, operation 304 of method 300 involves removing a first portion of a tie bar. For example, referring to partitioned leadframe preform 402 described above, operation 304 involves removing a first portion of at least one tie bar 422 and, since there are four tie bars 422 in this example, operation 304 may involve removing first portions of each of the four tic bars.

To illustrate, FIG. 5A shows side view 412 of partitioned leadframe preform 402. From side view 412, partitioned leadframe preform 402 is illustrated as being a flat sheet other than directly above the two tie bars 422 that can be seen from this perspective. As shown, a notch above each tie bar 422 illustrates the respective first portions of the tie bars that have been removed at operation 304. For example, these notches may have been made by etching, cutting, or otherwise removing material from the leadframe using any suitable technique.

As indicated in method 300 and as illustrated in FIG. 5B, operation 306 of method 300 involves attaching a first die 408-1 to partitioned leadframe preform 402. More particularly, as shown in FIG. 5B, first die 408-1 may be attached to inner leadframe portion 404-I by way of an attachment material 502. As shown, first die 408-1 may be attached to inner leadframe portion 404-I in a manner that electrically connects a bottom side of die 408-1 to inner leadframe portion 404-1. In other words, the attachment material 502 used to couple die 408-1 to inner leadframe portion 404-I may be conductive. As one example, operation 306 may be performed by way of a soldering operation (e.g., a solder reflow process) and attachment material 502 may be implemented by a soldering material. As another example, operation 306 may be performed by way of a sintering operation (e.g., a pressure sintering process) and attachment material 502 may be a sintering material (e.g., silver). In still other examples, operation 306 may be performed using other techniques and/or materials (e.g., a fusion bonding process, a conductive adhesive material, etc.).

As indicated in method 300 and as illustrated in FIG. 5C, operation 308 of method 300 involves attaching a second die 408-2 to partitioned leadframe preform 402. More particularly, as shown in FIG. 5C, second die 408-2 may be attached to outer leadframe portion 404-O. As with first die 408-1, second die 408-2 may be attached to outer leadframe portion 404-O in a manner that electrically connects a bottom side of die 408-2 to outer leadframe portion 404-O. Similarly as described above, it will be understood that the dies 408-1 and 408-2 may each be the same types of dies, different types of dies, or any suitable combination. As one example, first die 408-1 may be fabricated using a silicon substrate and second die 408-2 may be fabricated using a silicon carbide substrate.

Second die 408-2 is shown to be coupled to the outer leadframe portion 404-O using attachment material 502, which, as described above, may include solder, sintering material, a conductive adhesive, or another suitable material. In some examples, the attachment material used to attach die 408-2 may be the same as the attachment material used to attach die 408-1, while in other examples, different materials may be used for each bond as may serve a particular implementation. Also shown in FIG. 5C is a pressure chamber 504 that may be employed in certain implementations. For example, if attachment material 502 is a sintering material, both dies 408-1 and 408-2 may be positioned on the leadframe with the sintering material and the bonding of the dies to the leadframe may be performed by a pressure sintering operation using the pressure chamber 504. In implementations employing other techniques to attach the dies, no pressure chamber 504 may be needed.

With dies 408-1 and 408-2 in place, one or more interconnects may be added to the apparatus to make desired connections. Any given electrical connection may be optional and thus method 300 does not include an explicit operation detailing any particular electrical connection. FIG. 5D, however, shows that, at this stage of the manufacturing process (e.g., when the first portions of each of the plurality of tie bars 422 have been removed from partitioned leadframe preform 402 and the dies 408-1 and 408-2 have been attached), one or more electrically-conductive die interconnects 410 (similar to other interconnects described herein and also referred to as interconnects 410) may be added (e.g., using a wire bonding process or the like) to make desirable connections between the dies 408-1 and 408-2, the leadframe portions, and/or the leads 406. For example, FIG. 5D explicitly shows an interconnect connecting the top sides of dies 408-1 and 408-2, as well as an interconnect connecting die 408-1 to a lead 406 and another interconnect connecting die 408-2 to a different lead 406. While not explicitly shown in FIG. 5D, it will be understood that additional or alternate electrical interconnections may be made at this stage, such as a connection from inner leadframe portion 404-I to die 408-2, a connection from outer leadframe portion 404-O to die 408-1, a connection from either of the leadframe portions to any of the leads 406, or any other suitable connections.

As indicated in method 300 and as illustrated in FIG. 5E, operation 310 of method 300 involves encapsulating various elements of the apparatus in a molding material 414. As shown, for example, the elements encapsulated in molding material 414 at operation 310 may include the first die 408-1, the second die 408-2, and at least a portion of the partitioned leadframe preform 402 (e.g., portions of inner leadframe portion 404-I, outer leadframe portion 404-O, and leads 406). Since no added layers are added to the apparatus (e.g., DBC or other layers of material to isolate one or both dies 408-1 and 408-2 by suspending them above the leadframe), FIG. 5E shows that molding material 414 may advantageously maintain a relatively low profile shown by thickness 416 (understood to be a relatively thin profile compared to DBC examples such as the apparatus illustrated in FIG. 1C).

As indicated in method 300 and as illustrated in FIG. 5F, operation 312 of method 300 involves removing a second portion of the tie bars 422 such that inner leadframe portion 404-I becomes electrically isolated from outer leadframe portion 404-O. As mentioned above, while certain operations of method 300 may be performed concurrently or in a changed order from the order illustrated in method 300 (e.g., the dies attached at operations 306 and 308 could be attached concurrently or in the opposite order), it may be important for the removing of the respective second portions of the tie bars at operation 312 to be performed after the encapsulating of operation 310. This is because, as shown, the respective second portions of the tie bars 422 may comprise the remainder of the tie bars 422 that were not already removed as part of the first portion. In other words, as shown in FIG. 5F, there may be nothing left of tie bars 422 after the second portions of the tie bars have been removed. Rather, where the second portions used to be, the removing process performed at operation 312 may leave respective cavities 418.

The removing of the second portions (or remainders in some examples) of the various tie bars 422 (only two of the four of which are explicitly illustrated in the cross section of side view 412), may be performed in any suitable manner. For example, the second portions of the respective tic bars may be performed by cutting away the second portion of the tie bar using a mechanical tool, a laser, or another suitable cutting or etching tool. Depending on how this cutting is performed and the tool that is used, FIG. 5F shows that the respective cavities 418 left behind as artefacts of the cutting operation may have trapezoidal cross sections between inner leadframe portion 404-1 and outer leadframe portion 404-O. In other words, in this example, not only did the cutting away remove the entire remainder of what was left of the tie bars 422, but material of the leadframe portions was also removed as part of the cutting action. In other examples, the cross section of these cavities may have different shapes (e.g., rectangular, etc.) and may not necessarily reveal a complete removal of the entire tic bar 422. In any case, however, the tie bar may at least be broken and disconnected so as to impede current flow and block the electrical connection that the tie bar might otherwise provide between the inner leadframe portion 404-I and the outer leadframe portion 404-O. In other words, after the remove of the second portions of the tic bars 422 at operation 312, the inner and outer leadframe portions may be electrically isolated from one another, as shown in FIG. 5F and as described above.

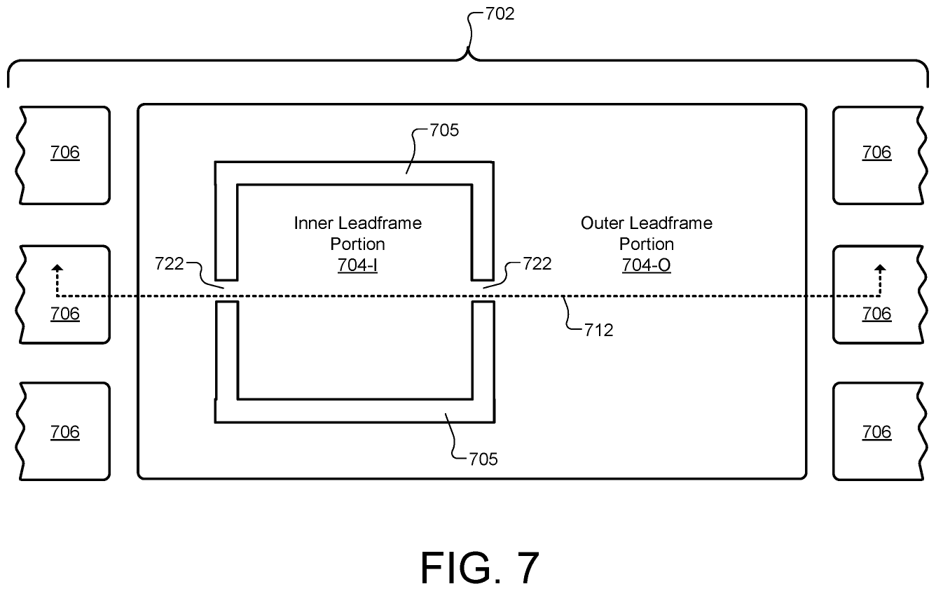

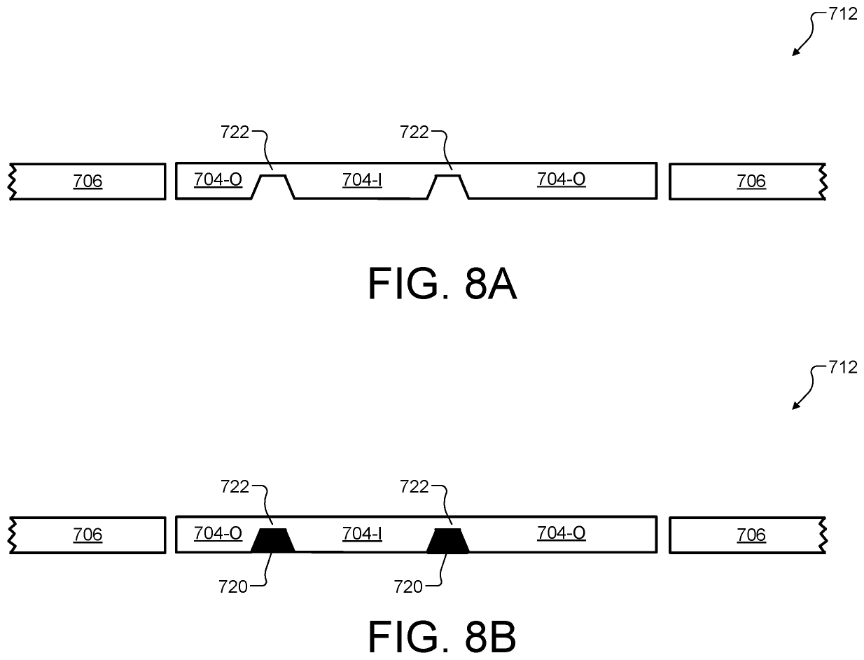

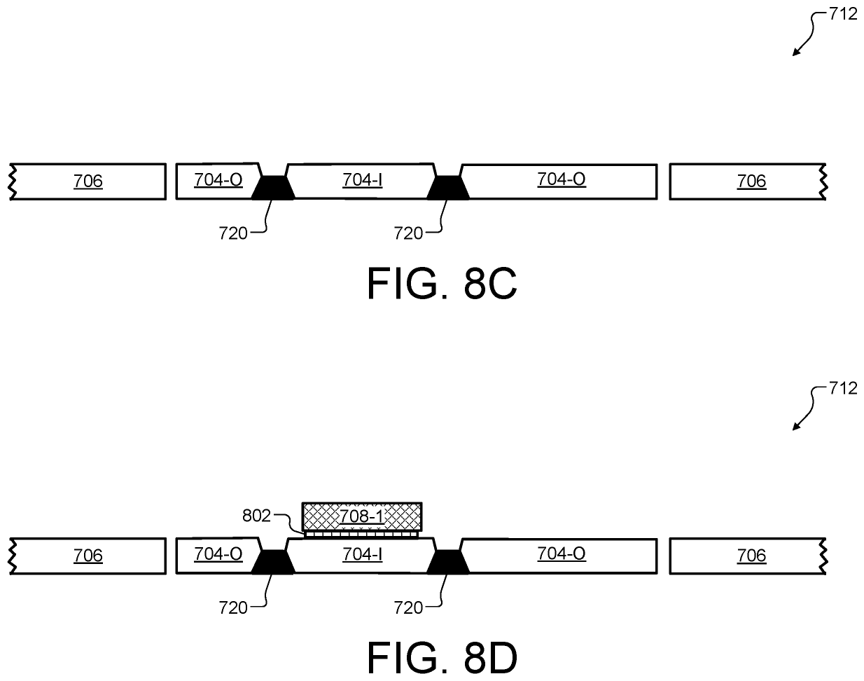

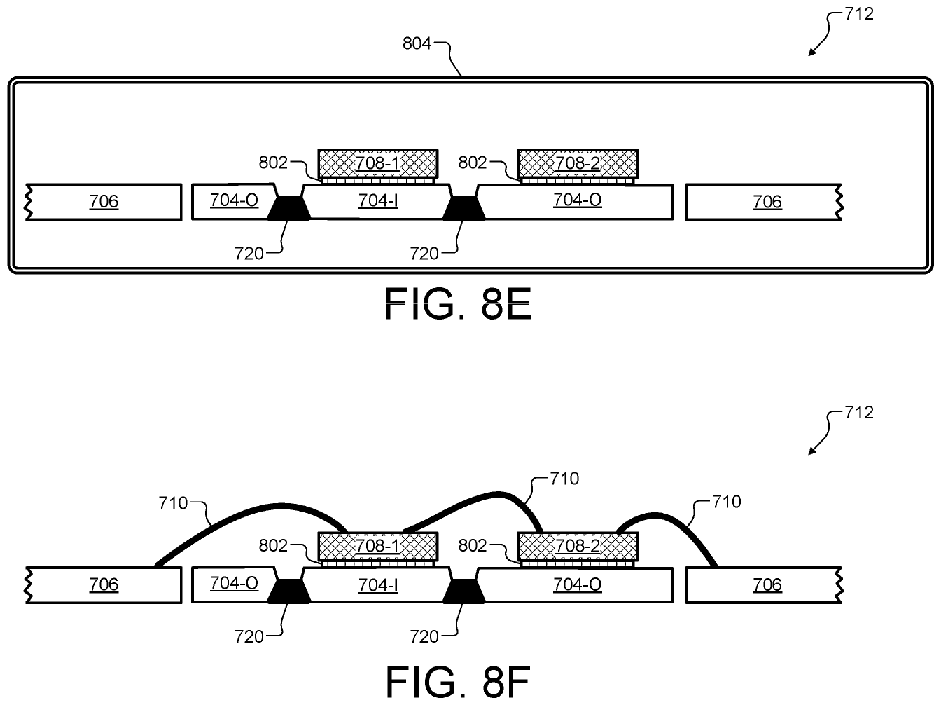

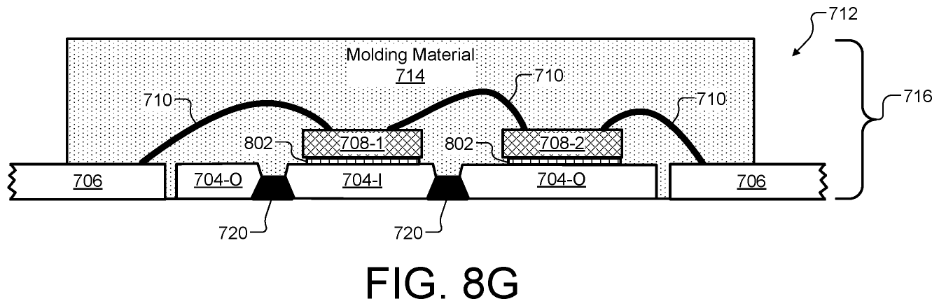

In FIG. 6, an illustrative method 600 for constructing a multi-die discrete electronic component with a partitioned leadframe is shown to include a plurality of operations 602-614 in accordance with principles described herein. More particularly, method 600 represents a method for constructing an apparatus such as the multi-die discrete electronic component described above in relation to FIG. 2C. While FIG. 6 shows illustrative operations 602-614 according to one implementation, other implementations of method 600 may omit, add to, reorder, and/or modify any of the operations 602-614 shown in FIG. 6 (although, as will be noted, the order of certain operations may be more relevant than others). In some examples, multiple operations shown in FIG. 6 or described in relation to FIG. 6 may be performed concurrently (e.g., in parallel) with one another, rather than being performed sequentially as illustrated and/or described. Each of operations 602-614 will now be described in more detail in relation to not only FIG. 6 but also FIGS. 7 and 8A-8G.

Operation 602 of method 600 involves forming a partitioned leadframe preform that includes an inner leadframe portion and an outer leadframe portion. Similarly as described above in relation to operation 302, the partitioned leadframe preform may be formed at operation 602 by stamping (e.g., stamping a copper sheet with a pattern of the partitioned leadframe preform), cutting, etching, or using any other suitable technique. FIG. 7 shows a top view of a partitioned leadframe preform 702 that may be used in performing method 600 in accordance with principles described herein. For example, partitioned leadframe preform 702 may represent the partitioned leadframe preform 702 that is formed at operation 602 (e.g., by stamping, cutting, etching, etc.). Similar to partitioned leadframe preform 402 described above, partitioned leadframe preform 702 is shown to include various elements numbered with a similar number scheme as previously used, including: an inner leadframe portion 704-I, an outer leadframe portion 704-O that fully surrounds inner leadframe portion 704-I, a space 705 (in two U-shaped portions for the preform) between inner leadframe portion 704-I and outer leadframe portion 704-O, and a plurality of leads 706 (shown in part in FIG. 7, though it will be understood that these leads may be full leads similar to those shown in other examples above).

A plurality of tie bars 722 is shown to break up space 705 between inner leadframe portion 704-I and outer leadframe portion 704-O. As with tic bars 422 described above, these tic bars 722 may hold inner leadframe portion 704-1 in place during much of the manufacturing process, but may ultimately be fully removed or at least broken so as to leave inner leadframe portion 704-I electrically isolated from outer leadframe portion 704-O in the final product. While each side of inner leadframe portion 404-I was shown to be connected to outer leadframe portion 404-O by one tie bar 422, this example shows only two tic bars 722 for the entire inner leadframe portion 704-I. It will be understood that this variation is shown for sake of illustration and to indicate another potential configuration for the partitioned leadframe preform. In reality, either partitioned leadframe preform 402 or partitioned leadframe preform 702 (or another partitioned leadframe preform with another configuration of tic bars) could be used for the manufacturing processes represented by either method 300 or 600. While partitioned leadframe preform 702 is shown in top view in FIG. 7, each of FIGS. 8A-8G will show partitioned leadframe preform 702 in a side view 712 whose perspective is shown by an indicator in FIG. 7.

Returning to FIG. 6, operation 604 of method 600 involves removing a first portion of a tic bar. For example, referring to partitioned leadframe preform 702 described above, operation 604 involves removing a first portion of at least one tie bar 722 and, since there are two tic bars 722 in this example, operation 604 may involve removing first portions of both of the two tic bars.

To illustrate, FIG. 8A shows side view 712 of partitioned leadframe preform 702. From side view 712, partitioned leadframe preform 702 is illustrated as being a flat sheet other than directly below the two tic bars 722. As shown, a notch below each tie bar 722 illustrates the respective first portions of the tie bars that have been removed at operation 604. For example, these notches may have been made by etching, cutting, or other suitable techniques for removing material from the leadframe. It is noted that operation 604 seems similar to operation 304 described above, except that, in this case, the first portions of the tic bars are on the bottom side of the partitioned leadframe preform rather than on the top side. While there may not be anything special about either side of the leadframe per se (e.g., the material may be the same on both sides and so forth), it will be made clear that the top side is different from the bottom side insofar as, in these examples, the top side, rather than the bottom side, is where elements such as dies, interconnects, and molding materials may be disposed. Accordingly, the first portions of tic bars 722 removed at operation 604 may be on a side opposite to where the dies and interconnects will be placed (which happens to be the top side in this example), while the first portions of tic bars 422 removed at operation 304 may be on the same side as where the dies and interconnects will be placed.

As indicated in method 600 and as illustrated in FIG. 8B, operation 606 of method 600 involves filling at least a portion of a space between inner leadframe portion 704-I and outer leadframe portion 704-O with a first molding material 720. This first molding material is shaded in black in FIG. 8B and other figures thereafter to differentiate the first molding material 720 from a second molding material 714 that will be added later (and corresponds more analogously in function to molding material 414 and other molding materials described above). It will be understood, however, that the first and second molding materials added at these different times may be the same or different materials (epoxies, resins, etc.) as may serve a particular implementation. FIG. 8B shows first molding material 720 that fills cavities (e.g., trapezoidal shaped cavities) left by the removal of the first portions of tic bars 722 at operation 604 and that otherwise is flush with the bottom side of partitioned leadframe preform 702. It will be understood, however, that operation 606 may include multiple sub-operations to achieve the configuration illustrated by FIG. 8B. For example, a layer of the first molding material 720 may be applied to a larger area of the bottom side of inner leadframe portion 704-I and outer leadframe portion 704-O, and, after the molding material 720 has cured, a grinding or other suitable operation may be performed to remove excess molding material until the only molding material left is the molding material 720 shown in the cavities beneath tic bars 722 in FIG. 8B.

As indicated in method 600 and as illustrated in FIG. 8C, operation 608 of method 600 involves removing a second portion of tie bars 722 such that inner leadframe portion 704-I becomes electrically isolated from outer leadframe portion 704-O. Similarly as mentioned above, while certain operations of method 600 may be performed concurrently or in a changed order from the order illustrated in method 600 (e.g., the dies attached at operations 610 and 612 described below could be attached concurrently or in the opposite order), it may be more important for the removing of the respective second portions of the tic bars at operation 608 to be performed after the filling of at least the portion of the space left between the leadframe portions (i.e., the cavities that are shown to be filled with first molding material 720). This is because, as shown, the respective second portions of the tic bars 722 may comprise the remainder of the tie bars 722 that were not already removed as part of the first portion. In other words, as shown in FIG. 8C, there may be nothing left of tic bars 722 after the second portions of the tie bars have been removed and first molding material 720 may thus hold the leadframe portions together for the remainder of the manufacturing process.

As described above with respect to the removing of the second portions (or remainders in some examples) of the tic bars 422, the removal of tic bars 722 may also be performed in any suitable manner. For example, the second portions of the respective tic bars may be performed by cutting away the second portion of the tie bar using a mechanical tool, a laser, or another suitable cutting or etching tool. Depending on how this cutting way is performed and the tool that is used, FIG. 8C shows that the respective cavities left behind as artefacts of the cutting operation may again have trapezoidal cross sections between inner leadframe portion 704-I and outer leadframe portion 704-O. In other examples, the cross section of these cavities may have different shapes (e.g., rectangular, etc.) and may not necessarily reveal a complete removal of the entire tic bar 722. Additionally or alternatively, a different procedure could be used to remove the second portions of the tie bars 722, such as grinding down an entirety of the leadframe portions until reaching first molding material 720. However the removal is performed at operation 608, the tie bars may be broken and disconnected so as to impede current flow and block the electrical connection that the tie bars might otherwise provide between inner leadframe portion 704-I and outer leadframe portion 704-O. In other words, as with tic bars 422 described above, after the removal of the second portions of the tie bars 722 at operation 608, the inner and outer leadframe portions may be electrically isolated from one another, as shown in FIG. 8C and as described above.

At FIG. 8C, the partitioned leadframe preform 702 is shown to be structurally stable and the leadframe portions are shown to be electrically isolated. Accordingly, once operations 602 through 608 have been performed to produce the partitioned leadframe preform 702 of FIG. 8C, it may be desirable for the remainder of operations 610-614 to be performed after this point in the process (i.e., after inner leadframe portion 704-I becomes electrically isolated from outer leadframe portion 704-O).

Accordingly, as indicated in method 600 and as illustrated in FIG. 8D, operation 610 of method 600 involves attaching a first die 708-1 to partitioned leadframe preform 702. More particularly, as shown in FIG. 8D, first die 708-1 may be attached to inner leadframe portion 704-I by way of an attachment material 802. As shown, first die 708-1 may be attached to inner leadframe portion 704-I in a manner that electrically connects a bottom side of die 708-1 to inner leadframe portion 704-1. In other words, the attachment material 802 used to couple die 708-1 to inner leadframe portion 704-I may be conductive. As one example, operation 610 may be performed by way of a soldering operation (e.g., a solder reflow process) and attachment material 802 may be implemented by a soldering material. As another example, operation 610 may be performed by way of a sintering operation (e.g., a pressure sintering process) and attachment material 802 may be a sintering material (e.g., silver). In still other examples, operation 610 may be performed using other techniques and/or materials (e.g., a fusion bonding process, a conductive adhesive material, etc.).

As indicated in method 600 and as illustrated in FIG. 8E, operation 612 of method 600 involves attaching a second die 708-2 to partitioned leadframe preform 702. More particularly, as shown in FIG. 8E, second die 708-2 may be attached to outer leadframe portion 704-O. As with first die 708-1, second die 708-2 may be attached to outer leadframe portion 704-O in a manner that electrically connects a bottom side of die 708-2 to outer leadframe portion 704-O. Similarly as described above, it will be understood that the dies 708-1 and 708-2 may each be the same types of dies, different types of dies, or any suitable combination. As one example, first die 708-1 may be fabricated using a silicon substrate and second die 708-2 may be fabricated using a silicon carbide substrate.

Second die 708-2 is shown to be coupled to the outer leadframe portion 704-O using attachment material 802, which, as described above, may include solder, sintering material, a conductive adhesive, or another suitable material. In some examples, the attachment material used to attach die 708-2 may be the same as the attachment material used to attach die 708-1, while in other examples, different materials may be used for each bond as may serve a particular implementation. Also shown in FIG. 8E is a pressure chamber 804 that may be employed in certain implementations. For example, if attachment material 802 is a sintering material, both dies 708-1 and 708-2 may be positioned on the leadframe with the sintering material and the bonding of the dies to the leadframe may be performed by a pressure sintering operation using the pressure chamber 804. In implementations employing other techniques to attach the dies, no pressure chamber 804 may be needed.

With dies 708-1 and 708-2 in place, one or more interconnects may be added to the apparatus to make desired connections. Any given electrical connection may be optional and thus method 600 does not include an explicit operation detailing any particular electrical connection. FIG. 8F, however, shows that, at this stage of the manufacturing process (e.g., when both portions of tie bars 722 have been removed and the dies 708-1 and 708-2 have been attached), one or more electrically-conductive die interconnects 710 (similar to other interconnects described herein and also referred to as interconnects 710) may be added (e.g., using a wire bonding process or the like) to make desirable connections between the dies 708-1 and 708-2 and/or the leads 706. For example, FIG. 8F explicitly shows an interconnect connecting the top sides of dies 708-1 and 708-2, as well as an interconnect connecting die 708-1 to a lead 706 and another interconnect connecting die 708-2 to a different lead 706. While not explicitly shown in FIG. 8F, it will be understood that additional or alternate electrical interconnections may be made at this stage, such as a connection from inner leadframe portion 704-I to die 708-2, a connection from outer leadframe portion 704-O to die 708-1, a connection from either of the leadframe portions to any of the leads 706, or any other suitable connections.

As indicated in method 600 and as illustrated in FIG. 8G, operation 614 of method 600 involves encapsulating various elements of the apparatus in a second molding material 714. As mentioned above, the second molding material may be different or the same as first molding material 720, though, as noted, the two molding materials are applied at different points in the process. As shown, elements encapsulated in molding material 714 at operation 614 may include the first die 708-1, the second die 708-2, and at least a portion of the partitioned leadframe preform 702 (e.g., portions of inner leadframe portion 704-I, outer leadframe portion 704-O, and leads 706). Since no layers are added to the apparatus (e.g., DBC or other layers of material to isolate one or both dies 708-1 and 708-2 by suspending them above the leadframe), FIG. 8G shows that molding material 714 may advantageously maintain a relatively low profile shown by thickness 716 (understood to be a relatively thin profile compared to DBC examples such as the apparatus illustrated in FIG. 1C).

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An apparatus, comprising:
a partitioned leadframe including an inner leadframe portion and an outer leadframe portion, the inner leadframe portion being at least partially surrounded by the outer leadframe portion and being electrically isolated from the outer leadframe portion;
a first die attached to the partitioned leadframe;
a second die attached to the partitioned leadframe; and
a molding material encapsulating the first die, the second die, and at least a portion of the partitioned leadframe, the molding material being recessed between the inner leadframe portion and the outer leadframe portion so as to leave a cavity on a side of the partitioned leadframe opposite the first die.

2. The apparatus of claim 1, wherein the first die is fabricated using a silicon substrate and the second die is fabricated using a silicon carbide substrate.

3. The apparatus of claim 1, wherein the first die and the second die are both fabricated using a substrate of a same substrate material.

4. The apparatus of claim 1, wherein:
the first die is attached to the inner leadframe portion;
the second die is attached to the outer leadframe portion;
the apparatus further comprises a die interconnect electrically connecting a top side of the first die to a top side of the second die; and
the molding material further encapsulates the die interconnect.

5. The apparatus of claim 1, wherein:
the first die is attached to the inner leadframe portion;
the second die is attached to the outer leadframe portion;
the apparatus further comprises a die interconnect electrically connecting the inner leadframe portion to a top side of the second die; and
a bottom side of the first die is electrically connected to the inner leadframe portion and the molding material further encapsulates the die interconnect.

6. The apparatus of claim 1, wherein:
the partitioned leadframe further includes a plurality of leads arranged adjacent to the outer leadframe portion; and
the apparatus further comprises a first die interconnect electrically connecting the first die to a first lead of the plurality of leads and a second die interconnect electrically connecting the second die to a second lead of the plurality of leads.

7. The apparatus of claim 1, wherein the cavity has a trapezoidal cross section between the inner leadframe portion and the outer leadframe portion.

8. The apparatus of claim 1, wherein:
the apparatus implements a discrete cascode circuit;
the first die is attached to the inner leadframe portion and implements a first transistor of the discrete cascode circuit; and
the second die is attached to the outer leadframe portion and implements a second transistor of the discrete cascode circuit.

9. An apparatus comprising:
A partitioned leadframe including an inner leadframe portion and an outer leadframe portion, the inner leadframe portion being at least partially surrounded by the outer leadframe portion and being and electrically isolated from the outer leadframe portion;
a first die attached to the partitioned leadframe;
a second die attached to the partitioned leadframe;
a first molding material filling at least a portion of a space between the inner leadframe portion and the outer leadframe portion; and
a second molding material encapsulating the first die, the second die, and at least a portion of the partitioned leadframe.

10. The apparatus of claim 9, wherein the first die is fabricated using a silicon substrate and the second die is fabricated using a silicon carbide substrate.

11. The apparatus of claim 9, wherein:
the first die is attached to the inner leadframe portion;
the second die is attached to the outer leadframe portion;
the apparatus further comprises a die interconnect electrically connecting the first die to the second die; and
the second molding material further encapsulates the die interconnect.

12. The apparatus of claim 9, wherein the first molding material is different from the second molding material.

13. A method comprising:
forming a partitioned leadframe preform that includes an inner leadframe portion and an outer leadframe portion, the inner leadframe portion being at least partially surrounded by the outer leadframe portion and being physically connected to the outer leadframe portion via a tie bar;
removing a first portion of the tie bar;
attaching a first die to the partitioned leadframe preform;
attaching a second die to the partitioned leadframe preform;
encapsulating the first die, the second die, and at least a portion of the partitioned leadframe preform in a molding material; and
removing, after the encapsulating, a second portion of the tie bar such that the inner leadframe portion becomes electrically isolated from the outer leadframe portion.

14. The method of claim 13, wherein the first die is fabricated using a silicon substrate and the second die is fabricated using a silicon carbide substrate.

15. The method of claim 13, wherein the removing the second portion of the tie bar is performed by cutting away the second portion of the tie bar using a mechanical tool or a laser.

16. The method of claim 13, wherein:
the tie bar is one of a plurality of tie bars physically connecting the inner leadframe portion to the outer leadframe portion;
the inner leadframe portion is shaped as a polygon having a plurality of sides that are each physically connected to the outer leadframe portion via at least one of the plurality of tie bars; and
the method further comprises:
removing, before the encapsulating, respective first portions of each of the plurality of tie bars other than the tie bar, and
removing, after the encapsulating, respective second portions of each of the plurality of tie bars other than the tie bar.

17. A method comprising:
forming a partitioned leadframe preform that includes an inner leadframe portion and an outer leadframe portion, the inner leadframe portion being at least partially surrounded by the outer leadframe portion and being physically connected to the outer leadframe portion via a tie bar;
removing a first portion of the tie bar;
filling at least a portion of a space between the inner leadframe portion and the outer leadframe portion with a first molding material;
removing, after the filling at least the portion of the space between the inner leadframe portion and the outer leadframe portion, a second portion of the tie bar such that the inner leadframe portion becomes electrically isolated from the outer leadframe portion; and
after the inner leadframe portion becomes electrically isolated from the outer leadframe portion:
attaching a first die to the partitioned leadframe preform;
attaching a second die to the partitioned leadframe preform; and
encapsulating the first die, the second die, and at least a portion of the partitioned leadframe preform in a second molding material.

18. The method of claim 17, wherein the first die is fabricated using a silicon substrate and the second die is fabricated using a silicon carbide substrate.

19. The method of claim 17, wherein the removing the second portion of the tie bar is performed by etching or grinding the second portion of the tie bar to thereby remove the tie bar.

20. The method of claim 17, wherein:
the tie bar is one of a plurality of tie bars physically connecting the inner leadframe portion to the outer leadframe portion;
the inner leadframe portion is shaped as a polygon having a plurality of sides that are each physically connected to the outer leadframe portion via at least one of the plurality of tie bars; and
the method further comprises:
removing, before the filling at least the portion of the space between the inner leadframe portion and the outer leadframe portion, respective first portions of each of the plurality of tie bars other than the tie bar, and
removing, after the filling at least the portion of the space between the inner leadframe portion and the outer leadframe portion, respective second portions of each of the plurality of tie bars other than the tie bar.
